(19) United States
(12) Patent Application Publication
(10) Pub. No.: US 2013/0262002 A1
(43) Pub. Date: Oct. 3, 2013

(54) MONITORING AND MATCHING BATTERIES AND BATTERY POWERED DEVICES

(71) Applicants: Patrick J. Braun, Pittsburgh, PA (US); Shawn T. Greyshock, Tarentum, PA (US); William A. Meyer, Wexford, PA (US)

(72) Inventors: Patrick J. Braun, Pittsburgh, PA (US); Shawn T. Greyshock, Tarentum, PA (US); William A. Meyer, Wexford, PA (US)

(73) Assignee: MCKESSON AUTOMATION INC., Cranberry, PA (US)

(21) Appl. No.: 13/435,805

(22) Filed: Mar. 30, 2012

(51) Int. Cl. G01R 31/36

(52) U.S. Cl. 702/63

(57) ABSTRACT

Provided herein are systems, methods and computer readable media for matching one or more batteries that were charged in a charging station with a remote device that is depleting its availble battery power. In providing such matching functionality, the system can be configured to, for example, monitor the amount of power the remote device, such as a rechargeable battery-powered device used in a hospital, requires over one or more periods of time, monitor the health of a number of batteries, match one or more of the batteries to the rechargeable battery-powered device, and then convey to a user which rechargeable battery-powered device should have its depleted battery replaced with a remotely-charged battery.

### FIELD

Embodiments of the invention relate, generally, to monitoring batteries and, in particular, to remotely monitoring rechargeable batteries deployed throughout a system.

### BACKGROUND

One way for doctors, anesthesiologists, nurses, pharmacists, technicians, and the like (referred to hereinafter as “users”) to store, transport and dispense medications to their patients is through the use of decentralized medication storage and dispensing devices (e.g., mobile medication dispensing carts, medication cabinets, nurse servers, etc.). In particular, a number of users may share a couple of medication carts, or similar mobile dispensing devices, for storing dispensing or delivering medications and/or medical supplies (e.g., syringes, gloves, etc.). For example, an anesthesia cart can be used by an anesthesiologist for storing all of the medications and dispensing/delivering supplies or equipment needed for the procedures (e.g., surgeries) that are planned for a given period of time (e.g., one workday).

In many instances, medication carts, and other mobile dispensing devices, may operate using power supplied from one or more rechargeable batteries, and operate as rechargeable battery-powered devices. While, in many instances, these rechargeable battery-powered devices can be plugged into an alternating current (“AC”) outlet and include recharging circuitry, there still is the possibility of the batteries going dead when the device is being moved from room to room, or throughout a dispensing route, and used continuously throughout a worker's shift. The devices may each include a local indicator showing the remaining battery power, but the users' main responsibility is often not equipment upkeep. As a result, each user may not always remember or be able to plug the device into an AC outlet, risking that the device will be without enough power to complete all the tasks for which the device is needed. Embodiments of the present invention overcome these problems, among others, faced by those that use and maintain rechargeable battery-powered devices, such as medication carts.

### BRIEF SUMMARY

In general, embodiments of the present invention provide improvements by, among other things, monitoring available power supplies, such as removable batteries, for mobile storage and dispensing devices, such as networked medication carts. In providing this functionality, systems, apparatus and/or computer readable media can be configured to execute instructions for determining an amount of energy stored by one or more batteries. Different batteries can be configured to store different amounts of energy, and batteries may store less energy as they age and/or depending on how they are used. In this regard, the amount of energy stored by a battery can be used to determine an amount of power the battery is expected to provide. The system may also implement instructions for selecting a rechargeable battery-powered device (e.g., medication cart) that needs a charged battery from among a plurality of rechargeable battery-powered devices (e.g., medication carts). For example, a medication cart can be selected based upon one of the batteries in the medication cart becoming depleted or nearly depleted. The medication cart may then be matched with a charged battery located remotely from the medication cart based at least partially on an expected power usage value associated with the selected medication cart.

Some embodiments can also be configured to determine the amount of power a battery may provide based on energy stored therein by analyzing the battery's usage history, the battery's length of service, the number of charge cycles the battery has undergone, the battery's average run time over a predetermined number of discharge cycles, and/or any other variables based on data generated by embodiments discussed herein.

In some embodiments, determining the battery to be installed into the selected rechargeable battery-powered device (e.g., medication cart) further comprises determining the battery power available to the selected rechargeable battery-powered device (e.g., medication cart). In some embodiments, the available battery power can be determined by, for example, determining a first amount of power a first battery is expected to provide the selected rechargeable battery-powered device; determining a second amount of power a second battery is expected to provide the selected rechargeable battery-powered device; and summing the first amount of power and the second amount of power to equal the available battery power. In other embodiments, the available battery power can be determined by, for example, determining a first amount of power that a first battery is expected to provide the selected rechargeable battery-powered device; determining a second amount of power that a second battery is expected to provide the selected rechargeable battery-powered device; and selecting the lesser of the first amount of power and the second amount of power as the available battery power.

In some embodiments, a rechargeable battery-powered device may be selected to have its battery swapped based at least partly on when the rechargeable battery-powered device is scheduled to be attended to by a user (e.g., restocked with medications and/or other supplies by a pharmacist, maintenance by an information technology user, or other otherwise attended to by any type of user). In this regard, the battery can be swapped when the user is at the medication cart for another reason.

In response to determining a battery is to be installed into a selected rechargeable battery-powered device, a display can be generated indicating where the battery is to be found by a user. For example, the user can be directed to a particular charging unit position. Similarly, in some embodiments, in response to determining the battery is to be installed into the selected rechargeable battery-powered device, a display can be generated indicating where the selected rechargeable battery-powered device is to be found by a user.

Some embodiments may also include a system comprising: communications circuitry configured to receive battery data indicating an amount of energy stored by a battery and receive an expected power usage value associated with a specific rechargeable battery-powered device; and a processor configured to determine an amount of power the battery is expected to provide from the amount of energy and determine which battery is to be installed into a particular rechargeable battery-powered device based at least partially on the expected power usage value associated with the rechargeable battery-powered device and the amount of power the battery is expected to provide.

Some embodiments may include a computer program product, the computer program product comprising at least one non-transitory computer-readable storage medium having computer-readable program code portions stored therein, the computer-readable program code portions comprising: an executable portion configured to receive battery data indicating an amount of energy stored by a battery; an executable portion configured to determine an amount of power the battery is expected to provide from the amount of energy; an executable portion configured to receive an expected power usage value associated with a rechargeable battery-powered device; and an executable portion configured to determine which battery is to be installed into the rechargeable battery-powered device based at least partially on the expected power usage value associated with the rechargeable battery-powered device and the amount of power the battery is expected to provide.

### BRIEF DESCRIPTION OF THE SEVERAL VIEWS OF THE DRAWING(S)

Having thus described embodiments of the invention in general terms, reference will now be made to the accompanying drawings, which are not necessarily drawn to scale, and wherein:

FIG. 1 shows a system diagram including medication dispensing carts, a centrally located network device and networked battery charging units in accordance with some embodiments discussed herein;

FIG. 2 shows a graph which represents the expected life of a battery based on the depth of discharge relative to the number of cycles in accordance with some embodiments discussed herein;

FIG. 3 shows a graph which represents how the number of cycles a battery experiences can affect the capacity of a battery measured in Amp hours in accordance with some embodiments discussed herein;

FIGS. 4A and 4B show graphs of example current draws for rechargeable battery-powered devices in accordance with some embodiments discussed herein;

FIG. 5 shows a schematic block diagram of circuitry that can be included in a computing device, such as a rechargeable battery-powered device, centrally located network device and/or networked battery charging unit, in accordance with some embodiments discussed herein;

FIGS. 6A and 6B show example charging cycles for batteries in accordance with some embodiments discussed herein;

FIG. 7 is a flow chart showing an exemplary process of matching a fully charged battery with a selected rechargeable battery-powered device in accordance with some embodiments discussed herein; and

FIGS. 8-16 show example graphical user interfaces that may be presented by various components of the system shown in FIG. 1 in accordance with some embodiments discussed herein.

### DETAILED DESCRIPTION

Embodiments of the present invention now will be described more fully hereinafter with reference to the accompanying drawings, in which some, but not all embodiments of the inventions are shown. Indeed, embodiments of the invention may be embodied in many different forms and should not be construed as limited to the embodiments set forth herein; rather, these embodiments are provided so that this disclosure will satisfy applicable legal requirements. Like numbers refer to like elements throughout.

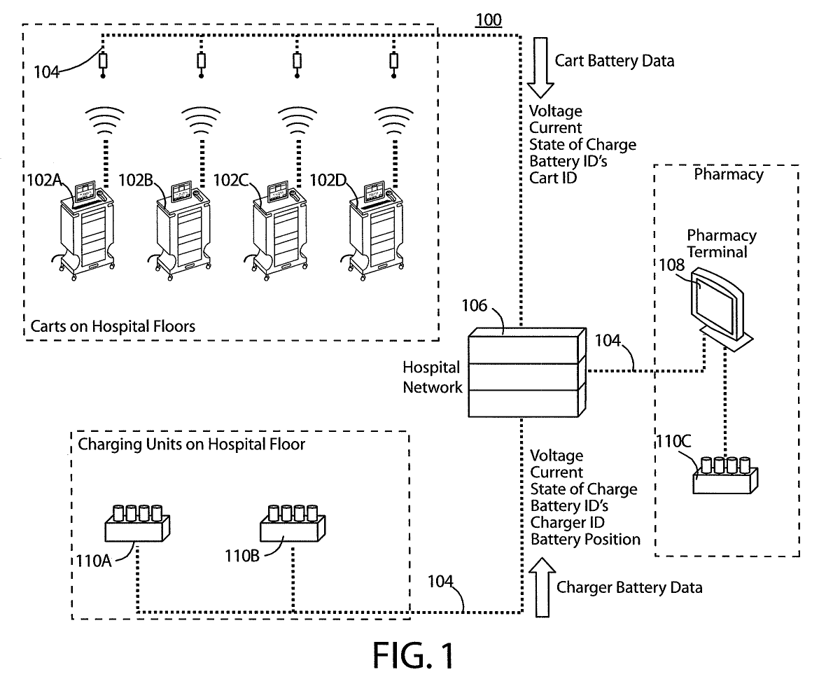

FIG. 1 shows system 100 in accordance with some embodiments discussed herein. While the following describes some embodiments of the present invention as including medication dispensing carts used in a healthcare environment, as one of ordinary skill in the art will recognize in light of this disclosure, embodiments of the present invention are not limited to the dispensing of medications or medical supplies using the carts described herein. In contrast, embodiments of the present invention may likewise be used in relation with any device that uses rechargeable batteries.

As shown, in some embodiments, system 100 may include mobile medication storage and delivery devices, such as rechargeable battery-powered devices 102A, 102B, 102C, and 102D. In this regard, rechargeable battery-powered devices 102A, 102B, 102C, and 102D can be configured to combine configurable drawer options, biometrics, advanced reporting capabilities and network integration to provide security, patient safety, efficiency and cost savings.

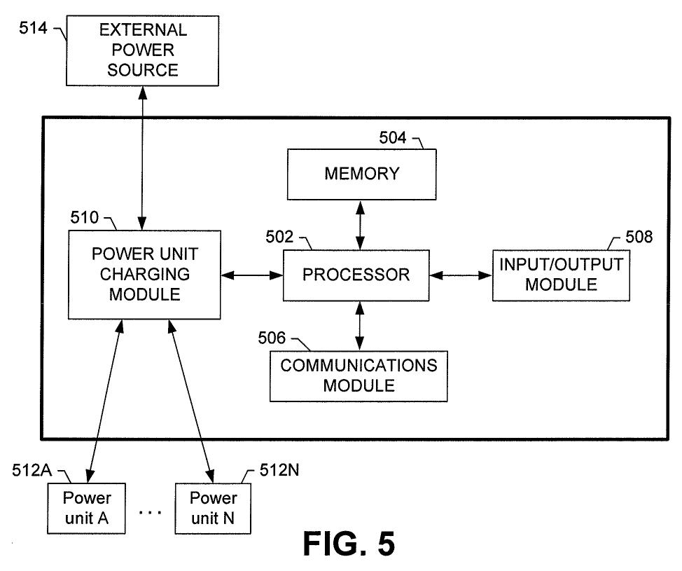

One or more of rechargeable battery-powered devices 102A, 102B, 102C, and 102D may include a computing device (e.g., desktop computer, laptop computer, tablet, or any other type of computing device), the circuitry of which is discussed in more detail below in connection with, e.g., FIG. 5. The computing device of each of rechargeable battery-powered devices 102A, 102B, 102C, and 102D can be used to monitor, store, access and/or upload information associated with, for example, one or more batteries available for use by the rechargeable battery-powered device (including the battery type, remaining power, usage time, battery identifier, among other things), and/or monitor power usage data of the associated rechargeable battery-powered device (e.g., amount of power required over an average shift, amount of power required over a predetermined period of time, amount of power usually required over a given time of day, among other things). The computing device of each of rechargeable battery-powered devices 102A, 102B, 102C, and 102D can also or instead each be used to monitor, store, access and upload information associated with medications, and dispensing/delivery devices and other supplies stored in the rechargeable battery-powered device, as well as information associated with the patients for whom medications and supplies may be dispensed from the rechargeable battery-powered device at a given point in time. In some embodiments, some or all of this information may be stored locally in memory (such as memory 504 discussed in connection with, e.g., FIG. 5) associated with the computing device of each of rechargeable battery-powered devices 102A, 102B, 102C, and 102D. For example, information associated with each battery being used to power a rechargeable battery-powered device 102A, 102B, 102C, or 102D may be inputted (e.g., by a user and/or automatically from a barcode scanner and/or radio frequency identification (“RFID”) reader) by the computing device at or near the time when the rechargeable battery-powered device receives a new battery. Alternatively, or in addition, some or all of the information associated with all of the available batteries may be downloaded (e.g., received) and/or uploaded (e.g., transmitted) by each computing device, for example via communications network 104 (which may be wired and/or wireless), from and/or to central device 106.

In this regard, system 100 is shown as an exemplary networked system that may benefit from embodiments provided herein. System 100 can be associated with a healthcare department, healthcare facility and/or entire enterprise in which rechargeable battery-powered devices 102A, 102B, 102C, and 102D and/or other types of battery-powered devices are being used or available for use. Network 104 may include any wired or wireless communication network including, for example, a wired or wireless local area network (LAN), personal area network (PAN), metropolitan area network (MAN), wide area network (WAN), or the like, as well as any hardware, software and/or firmware required to implement it (such as, e.g., network routers, etc.).

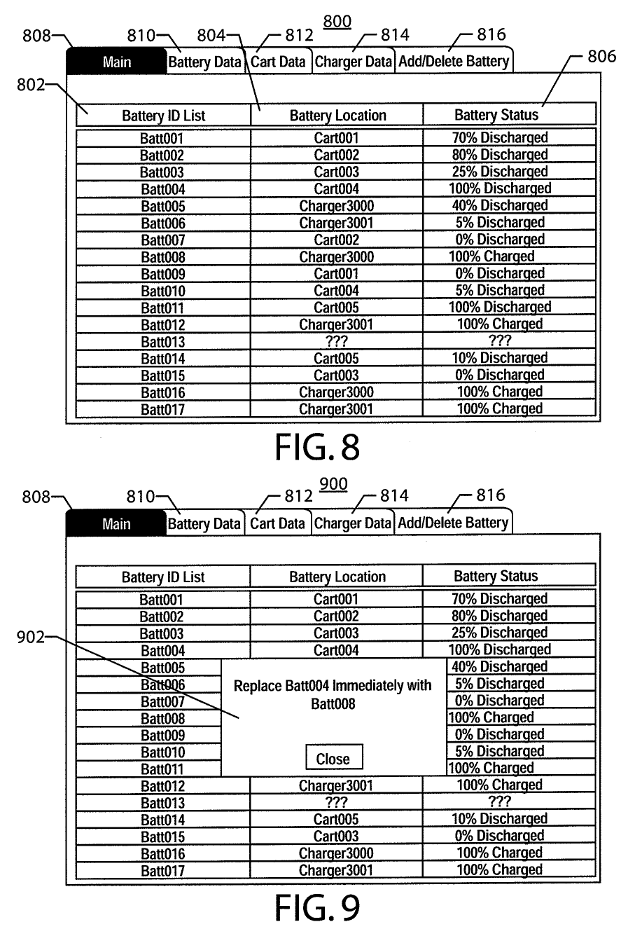

One or more of rechargeable battery-powered devices 102A, 102B, 102C, and 102D can be configured to receive and/or present information regarding, for example, one or more of its available batteries and/or other types available power sources. For example, a display screen can be configured to present battery status information, battery identifier information, and/or any other type of user-understandable information related to the available power source(s). The information presented by the display screen and/or other output components discussed herein (including that discussed in connection with FIGS. 8-16) can be based on data signals generated locally at the rechargeable battery-powered device and/or at a remote device, such as central device 106, pharmacy terminal 108, one or more of battery charging units 110A, 110B, and 110C, and/or any other remote device. In addition to a display screen, each of rechargeable battery-powered devices 102A, 102B, 102C, and 102D may also include a keyboard, a speaker, a barcode reader, a RFID reader, a biometric scanner, touch-sensitive screen, among other types of input/output components that can receive and/or present battery and/or any other type of information. Example user input/output circuitry is discussed further in connection with FIG. 5.

System 100 can be configured to implement associated methods for monitoring and/or matching removable, rechargeable batteries with rechargeable battery-powered devices 102A, 102B, 102C, and 102D. In some embodiments, rechargeable battery-powered devices 102A, 102B, 102C, and 102D may or may not be configured to charge their batteries by being plugged into a power source (such as an alternating current (“AC”) outlet in a wall). In some embodiments, the batteries used by the rechargeable battery-powered devices 102A, 102B, 102C, and 102D can be recharged by being physically removed and placed into another device, sometimes referred to herein as a “battery charging unit,” such as battery charging units 110A, 110B, and 110C shown in FIG. 1. Battery charging units 110A and 110B are shown as being included in a separate area of the same building (e.g., in the same or different room, floor, wing, etc.) as rechargeable battery-powered devices 102A, 102B, 102C, and/or 102D, while battery charging unit 110C is shown in FIG. 1 as being located in a remote pharmacy.

In an AC charging scenario, nurses and/or other users may be tasked with being responsible for recharging batteries of rechargeable battery-powered devices 102A, 102B, 102C, and 102D based on information provided by the integrated display screen of each rechargeable battery-powered device. For example, each rechargeable battery-powered device may be configured to present one or more types of remaining battery power indicators (such as those commonly provided by many battery charging devices) and/or specialized prompts when battery power drops below one or more predefined threshold(s) (such as, e.g., when battery power is less than 5%). However, using nurses as an example, their main responsibility is patient care, not equipment upkeep and, as a result, nurses may not always remember or have the opportunity to plug-in the rechargeable battery-powered device they are using, which may sometimes cause the rechargeable battery-powered device to not have enough battery power to complete a medication round or shift at the hospital. Charging times for some batteries can be relatively long when a battery is depleted. Hence, each nurse may be required to continuously plug-in and unplug the rechargeable battery-powered device to complete, for example, a med pass.

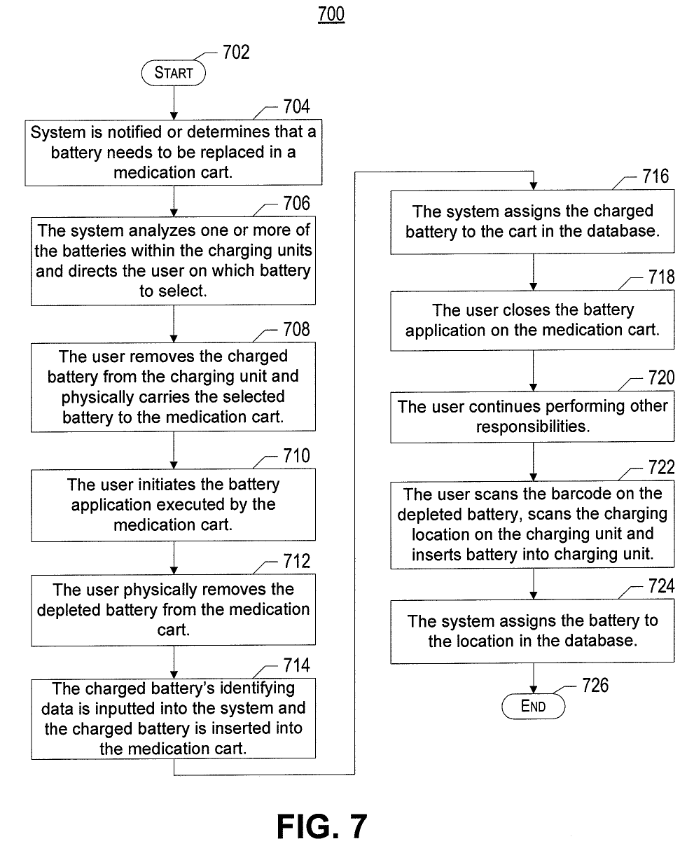

When rechargeable battery-powered devices 102A, 102B, 102C, and 102D are configured to receive removable batteries, their batteries can be swapped out for fully charged batteries. Such a configuration can help relieve nurses from at least some of the responsibility of keeping the batteries charged in the rechargeable battery-powered devices they use to tend to patients. The fully-charged batteries can come from, for example, one or more of battery charging units 110A, 110B, and 110C. In some embodiments, one or more components of system 100, such as central device 106, can be configured to match one or more of the partially or fully charged batteries in charging units 110A, 110B, and/or 110C with each of rechargeable battery-powered devices 102A, 102B, 102C, and 102D as the batteries in rechargeable battery-powered devices 102A, 102B, 102C, and 102D are depleted of energy. Example methods and graphical user interface displays that may help facilitate determining and conveying to a user which charged batteries have been matched with which rechargeable battery-powered devices are discussed in connection with FIGS. 7-16.

In determining which battery or batteries should be matched to which rechargeable battery-powered device, system 100 can be configured to process a variety of variables relating to, for example, the health of various batteries and/or power usage requirements of various rechargeable battery-powered devices. For example, the usage history of all available batteries can be considered, among other things, when determining which battery of charging units 110A, 110B, and/or 110C should be matched to one of rechargeable battery-powered devices 102A, 102B, 102C, and 102D, since the usage history of a battery, for example, can impact the amount of power the battery can provide.

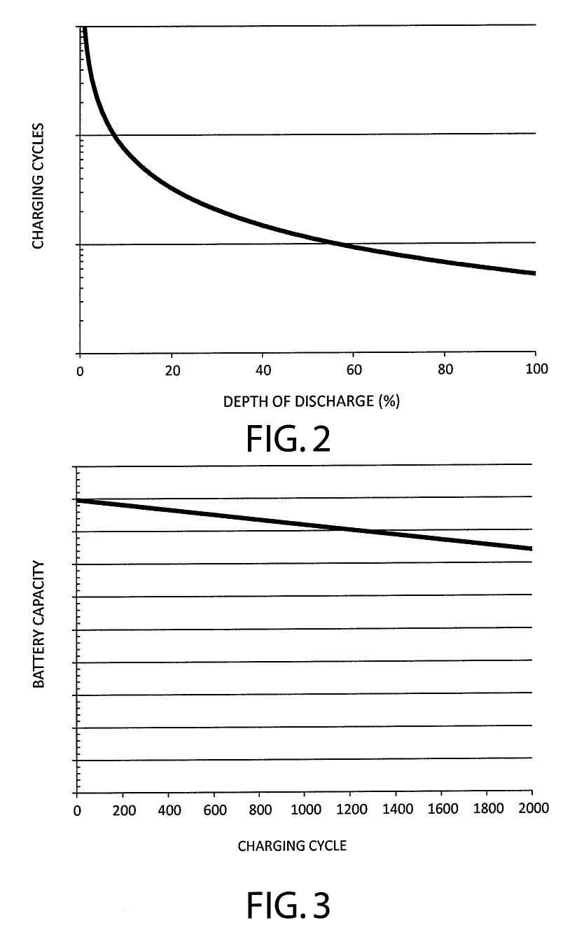

In this regard, system 100, and in particular the central device 106, can be configured to monitor, log and process each of the batteries' usage histories within system 100, including each battery's age and average depth of discharge. As batteries age, are used, and are recharged, their ability to hold a charge diminishes. For example, FIG. 2 shows a graph which represents the expected life of a battery based on the average depth of discharge (“DOD”) that the battery is allowed to experience before being recharged to full capacity, where the life of the battery is calculated in terms of the number of discharge and recharge cycles it can undergo. As shown in FIG. 2, the average amount a battery is discharged (i.e., the % DOD) has an inverse relationship to the number of times the battery can be recharged. System 100 can, therefore, be configured to monitor how many times a battery has been discharged, determine the type of battery, and calculate the life expectancy or expected number of discharge/recharge cycles for that battery.

FIG. 3 shows another graph which represents how the number of charge/discharge cycles a battery has experienced can affect the capacity of a battery measured in Amp hours (“Ah”). The graph of FIG. 3 illustrates how, the capacity of the battery diminishes as the number of cycles undergone increases. As such, some embodiments of system 100 can be configured to determine how much power a battery is expected to provide from the energy stored therein. As used herein, “energy” refers to potential electrical energy that may be stored in a battery, and “power” refers to the time rate at which energy is transferred to/from a battery. The amount of energy stored in a battery can be determined by measuring, for example, the voltage potential of the battery relative to a ground.

As a result, when a fully-charged, but old battery (e.g., a battery that has experienced 2000 cycles) is used to replace a depleted battery in a rechargeable battery-powered device, a user may be led to believe the fully-charged battery will last, for example, an entire med shift unless the calculations discussed herein are performed by system 100. System 100 can be configured to inform its users that the fully-charged battery may only last a fraction of that time (depending on, for example, the amount of power historically required by the particular rechargeable battery-powered device to complete the med shift). In other words, system 100 can be configured to take into consideration that not all batteries perform equally because of each battery's unique usage history.

System 100 can also be configured to take into consideration that rechargeable battery-powered devices require different amounts of power over a predetermined period. Some rechargeable battery-powered devices may require more power during operation than others. For example, rechargeable battery-powered device 102A may require, on average, twice the amount of power during a given day than rechargeable battery-powered device 102D requires. In this regard, dispensing device 102A may be deployed in a department of a hospital, such as a recovery ward, where a nurse rolls dispensing device 102D from patient to patient dispensing medication throughout an entire shift, whereas rechargeable battery-powered device 102D may be used in a pediatric ward where only some patients are prescribed medication.

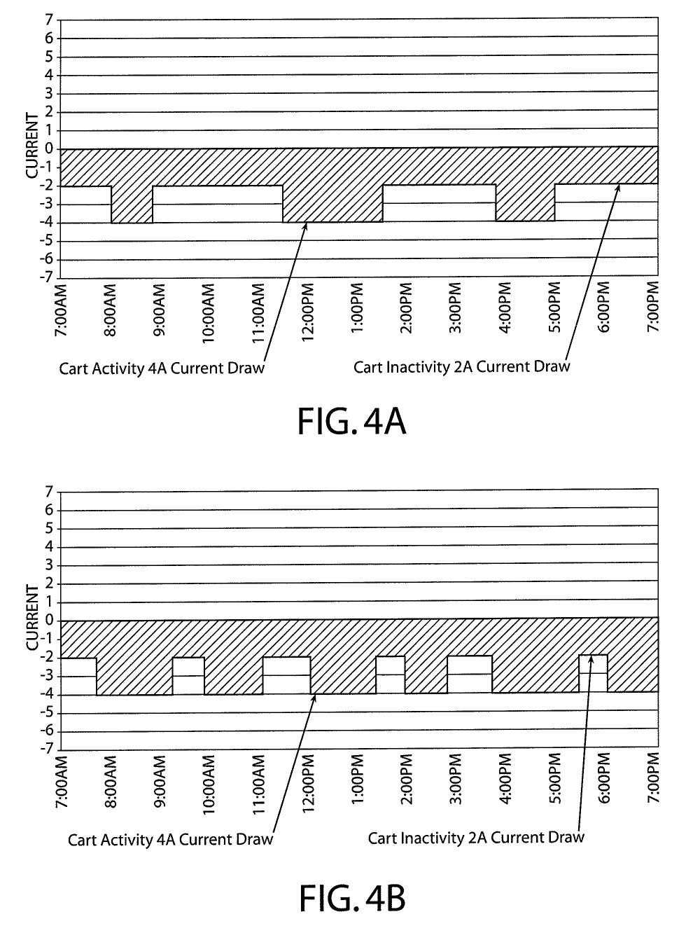

FIGS. 4A and 4B show examples of two rechargeable battery-powered devices, such as rechargeable battery-powered devices 102B and 102C, respectively, that may have varying power requirements throughout a normal day (and/or other 12 hour time period). System 100 can be configured to monitor cart activity of rechargeable battery-powered devices 102B and 102C to help determine which rechargeable battery-powered device requires more power, so that rechargeable battery-powered device receives the best battery or batteries available. For example, monitoring cart activity may include a power management application running on each rechargeable battery-powered device to monitor and log when the cart is inactive, when components like the monitor and computing device may go into a low power mode. By regularly monitoring current draw from each rechargeable battery-powered device, a power usage value can be developed based on a power usage profile that shows how often the cart is in use. FIG. 4A shows a first example of a power usage profile based on the current draw of rechargeable battery-powered device 102B over a twelve hour period. When rechargeable battery-powered device 102B is being used, for example, the current draw can be greater (e.g., averaging 4 amps) as compared to when rechargeable battery-powered device 102B is in standby mode or otherwise not being used (e.g., averaging 2 amps of current draw). In this regard, FIG. 4A shows that rechargeable battery-powered device 102B has a power usage value of approximately a 35% duty cycle over 12 hour timeframe shown. FIG. 4B shows rechargeable battery-powered device 102C that has, relatively, a much higher power usage value, which is shown as a 60% duty cycle over the same 12 hour timeframe. By configuring each rechargeable battery-powered device of system 100 to locally monitor its power usage requirements during operation, system 100 can match the best batteries to the most utilized rechargeable battery-powered devices by processing the cart power requirement information (based on, among other things, the power usage information being captured, uploaded, transmitted and/or otherwise processed by components of system 100, including central device 106) in connection with the battery status information (which may be obtained through one or more charging units, as discussed below, and/or by monitoring one or more rechargeable battery-powered devices' duty cycles through current draw).

Hence, some embodiments of system 100 discussed herein can be configured to, for example, monitor the amount of power a rechargeable battery-powered device requires over one or more periods (wherein each “period” may be measured by time, a predetermined number of user interactions, one or more med shifts, and/or any other suitable units), monitoring the health of a battery (based on, e.g., the battery's age, ability to hold a charge, number of depletion/recharge cycles, among other factors that may impact the amount of power a battery can supply from its stored energy), matching one or more batteries (including those being charged by a remote charging unit) to a rechargeable battery-powered device, and then conveying to a user which rechargeable battery-powered device should receive which fully-charged battery. (Example machine-generated graphical user interfaces are shown in FIGS. 8-16.) In providing such functionality, system 100 can be further distilled into its various machine components that include hardware, such as that shown in FIG. 5.

FIG. 5 shows a schematic block diagram of an apparatus 500, which may be a rechargeable battery-powered device (such as rechargeable battery-powered devices 102A, 102B, 102C or 102D), a centrally located network device (such as central device 106, which may be configured to function as one or more backend data server(s), network database(s), cloud computing device(s), among other things), networked battery charging unit (such as, charging units 110A, 110B, or 110C), and/or any other component of system 100 that may be used to aid in providing the functionality discussed herein. Although apparatus 500 is discussed generally in connection with all these devices, various examples unique to the example devices are provided herein. It should also be understood, however, that one or more of the apparatuses discussed herein may include alternative means for performing one or more like functions, without departing from the spirit and scope of embodiments discussed herein.

As illustrated in FIG. 5, in accordance with some example embodiments, apparatus 500 includes various means, such as processor 502, memory 504, communications module 506, input/output module 508 and/or power unit charging module 510 for performing the various functions herein described. As referred to herein, “module” includes hardware, software and/or firmware configured to perform one or more particular functions. In this regard, the means of apparatus 500 as described herein may be embodied as, for example, circuitry, hardware elements (e.g., a suitably programmed processor, combinational logic circuit, and/or the like), a computer program product comprising computer-readable program instructions stored on a non-transitory computer-readable medium (e.g., memory 504) that is executable by a suitably configured processing device (e.g., processor 502), or some combination thereof.

Processor 502 may, for example, be embodied as various means including one or more microprocessors with accompanying digital signal processor(s), one or more processor(s) without an accompanying digital signal processor, one or more coprocessors, one or more multi-core processors, one or more controllers, processing circuitry, one or more computers, various other processing elements including integrated circuits such as, for example, an ASIC (application specific integrated circuit) or FPGA (field programmable gate array), or some combination thereof. Accordingly, although illustrated in FIG. 5 as a single processor, in some embodiments processor 502 comprises a plurality of processors. The plurality of processors may be embodied on a single computing device or may be distributed across a plurality of computing devices collectively configured to function as apparatus 500. The plurality of processors may be in operative communication with each other and may be collectively configured to perform one or more functionalities of apparatus 500 as described herein. In an example embodiment, processor 502 is configured to execute instructions stored in memory 504 or otherwise accessible to processor 502. These instructions, when executed by processor 502, may cause apparatus 500 to perform one or more of the functionalities of apparatus 500 as described herein.

For example, when apparatus 500 is implemented as a rechargeable battery-powered device (such as rechargeable battery-powered device 102A), processor 502 can be configured to monitor the amount of power drawn from the energy stored in its one or more batteries (and/or other power sources) over a given period of time (graphical examples of such data are shown in FIGS. 4A and 4B). As another example, when apparatus 500 is implemented as central computing device (such as central device 106), processor 502 can be configured to determine the power requirement of one or more remotely located rechargeable battery-powered devices based on data received over network 104, the data representing the power drawn over time by the one or more rechargeable battery-powered devices.

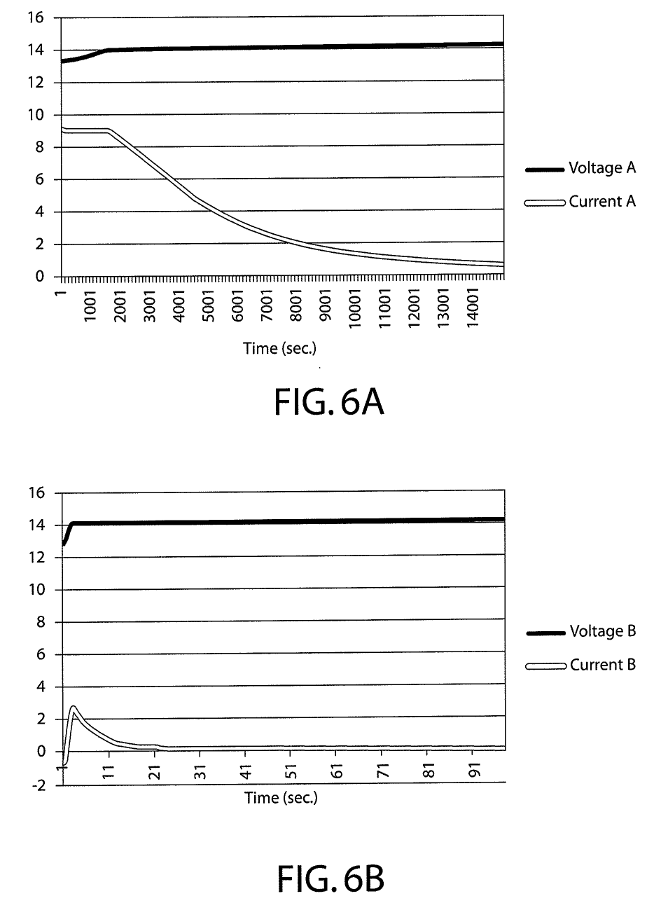

As a third example, when apparatus 500 is implemented as a battery charging unit (such charging unit 110A), processor 502 can be configured to determine the health of the battery and/or when the battery is fully charged. In this regard, as shown in FIGS. 6A and 6B, the health of a battery can be determined by monitoring the charging of a battery, uploading the results of the monitoring (to, e.g., a central device) and/or saving the results locally to memory 504, and then referencing the charging history of each battery to continuously calculate the relative health of each battery. For example, FIG. 6A shows a charging cycle for a relatively healthy battery. The battery of FIG. 6A takes maximum current at the beginning of the cycle and then gradually reduces to zero over an extended time (which is shown as 4 hours in FIG. 6A). FIG. 6B, on the other hand, shows a representative graph of an example charging cycle for a relatively unhealthy battery that is not capable of accepting a charge or providing much power from its charge. The initial current in FIG. 6B is a third of the maximum possible current and the current relatively quickly drops to zero in 1.5 minutes. FIGS. 6A and 6B show two extremes, but as batteries of the same type age and are used their profiles should generally fall between these two limits and battery status can be determined by processor 502 analyzing this data. In some embodiments, the processor of central device 106 and/or any other component of system 100 can be configured to determine the relative health of one or more remotely located batteries and/or the amount of power expected to be provided when fully-charged.

Returning to the discussion of FIG. 5, whether configured by hardware, firmware/software methods, or by a combination thereof, processor 502 may comprise an entity capable of performing operations according to embodiments of the present invention while configured accordingly. Thus, for example, when processor 502 is embodied as an ASIC, FPGA or the like, processor 502 may comprise specifically configured hardware for conducting one or more operations described herein. Alternatively, as another example, when processor 502 is embodied as an executor of instructions, such as may be stored in memory 504, the instructions may specifically configure processor 502 to perform one or more algorithms and operations described herein.

Memory 504 may comprise, for example, volatile memory, non-volatile memory, or some combination thereof. Although illustrated in FIG. 5 as a single memory, memory 504 may comprise a plurality of memory components. The plurality of memory components may be embodied on a single computing device or distributed across a plurality of computing devices. In various embodiments, memory 504 may comprise, for example, a hard disk, random access memory, cache memory, flash memory, a compact disc read only memory (CD-ROM), digital versatile disc read only memory (DVD-ROM), an optical disc, circuitry configured to store information, or some combination thereof. Memory 504 may be configured to store information, data, applications, instructions, or the like for enabling apparatus 500 to carry out various functions in accordance with example embodiments of the present invention. For example, in at least some embodiments, memory 504 is configured to buffer input data for processing by processor 502. Additionally or alternatively, in at least some embodiments, memory 504 is configured to store program instructions for execution by processor 502. Memory 504 may store information in the form of static and/or dynamic information. This stored information may be stored and/or used by apparatus 500 during the course of performing its functionalities.

For example, when apparatus 500 is implemented as a rechargeable battery-powered device (such as rechargeable battery-powered device 102A, 102B, 102C, or 102D), memory 504 can be configured to store data associated with one or more batteries (and/or other available power sources) being used to power apparatus 500. For example, for each battery being used, the amount of power drawn from the battery's stored energy over a given period of time, battery identifier information, the current DOD, the amount of current being supplied by the battery, and/or the voltage potential of the battery may be stored in memory 504. As another example, when apparatus 500 is implemented as a rechargeable battery-powered device, memory 504 may also be configured to store rechargeable battery-powered device identifying data, rechargeable battery-powered device power usage information, rechargeable battery-powered device location information (based on, e.g., global positioning system data, real-time locating system data, facility room information, hospital ward information, among other things), user-related information (e.g., name and employee identification information of one or more users currently or previously using apparatus 500), medication information (e.g., medication supply quantities, narcotic warning information, restocking schedule information, medication pocket location information, etc.), and/or any other information that may be helpful in enabling the functionality discussed herein.

As another example, when apparatus 500 is implemented as a centrally-located device (such as a cloud computing device, database manager, network server, etc., which are represented by central device 106 in FIG. 1), any data generated by and/or received from the devices of system 100 may be stored in memory 504. Additionally or alternatively, instructions for matching batteries currently associated with one of the charging devices to one of the rechargeable battery-powered devices can also be stored in memory 504 for execution by processor 502 when apparatus 500 is implemented as central device 500 (and/or any other component of system 100 that may be configured to perform the matching functionality discussed herein).

As yet another example, when apparatus 500 is implemented as a charging unit (such charging unit 110A, 110B, or 110C), memory 504 can be configured to store charging profiles generated by the charging unit (such as those discussed in connection with FIGS. 6A and 6B), battery position information, charger identifying information, battery identifying information, the current state of the charge of the batteries coupled to apparatus 500, and/or any other data associated with a charging unit.

Apparatus 500 may also be implemented as a personal computer and/or other networked device (e.g., cellular phone, tablet computer, etc.) that may be used for any suitable purpose. For example, when apparatus 500 is configured to be implemented as pharmacy terminal 108, memory 504 can be configured to store data associated with and/or received from charging unit 110C. As another example, apparatus 500 can be configured to store schedules related to restocking of medications and other supplies dispensed from one or more rechargeable battery-powered devices included in system 100. Such restocking and other types of schedules (including employee work schedules) can be used by system 100 to determine when to swap a battery in a rechargeable battery-powered device and which user to instruct to do so (i.e., which device to send the notification to).

Communications module 506 may be embodied as any device or means embodied in circuitry, hardware, a computer program product comprising computer readable program instructions stored on a computer readable medium (e.g., memory 504) and executed by a processing device (e.g., processor 502), or a combination thereof that is configured to receive and/or transmit data from/to another device, such as, for example, a second apparatus 500 and/or the like. In some embodiments, communications module 506 (like other components discussed herein) can be at least partially embodied as or otherwise controlled by processor 502. In this regard, communications module 506 may be in communication with processor 502, such as via a bus. Communications module 506 may include, for example, an antenna, a transmitter, a receiver, a transceiver, network interface card and/or supporting hardware and/or firmware/software for enabling communications with another computing device. Communications module 506 may be configured to receive and/or transmit any data that may be stored by memory 504 using any protocol that may be used for communications between computing devices. Communications module 506 may additionally or alternatively be in communication with the memory 504, input/output module 508 and/or any other component of apparatus 500, such as via a bus.

Input/output module 508 may be in communication with processor 502 to receive an indication of a user input and/or to provide an audible, visual, mechanical, or other output to a user. Some example visual outputs that may be provided to a user by apparatus 500 are discussed in connection with FIGS. 8-16. As such, input/output module 508 may include support, for example, for a keyboard, a mouse, a joystick, a display, a touch screen display, a microphone, a speaker, a RFID reader, barcode reader, biometric scanner, and/or other input/output mechanisms. In embodiments wherein apparatus 500 is embodied as a server or battery charging unit, aspects of input/output module 508 may be reduced as compared to embodiments where apparatus 500 is implemented as a user terminal (e.g., pharmacy terminal 108) or other type of device designed for complex user interactions (such as a rechargeable battery-powered device configured to dispense narcotics). In some embodiments (like other components discussed herein), input/output module 508 may even be eliminated from apparatus 500. Alternatively, such as in embodiments wherein apparatus 500 is embodied as a server and/or charging unit, at least some aspects of input/output module 508 may be embodied on an apparatus used by a user that is in communication with apparatus 500, such as for example, pharmacy terminal 108. Input/output module 508 may be in communication with the memory 504, communications module 506, and/or any other component(s), such as via a bus. Although more than one input/output module and/or other component can be included in apparatus 500, only one is shown in FIG. 5 to avoid overcomplicating the drawing (like the other components discussed herein).

Power unit charging module 510 can include any hardware, firmware and/or software useful for charging one or more power units, such as power unit 512A through power unit 512N. For example, power units 512A-512N can be one or more battery packs and/or other types of batteries that are recharged when an external power source, such as external power source 514 is providing a surplus of power to apparatus 500. External power source 514 can be an AC outlet, a solar panel, and/or any other suitable source of power. Power unit charging module 510 can include an alternating current-to-direct current converter (“AC/DC converter”) and/or any other component useful for charging a depleted power unit.

For example, when apparatus 500 is implemented as a rechargeable battery-powered device, power unit charging module 510 can be configured to monitor the health of the power units 512A-512N (e.g., there may be two battery packs included in apparatus 500) both when they are charged and when they are drained during use. The data collected during the monitoring process may be stored (by, e.g., memory 504) and/or processed (by, e.g., processor 502) into statistical data, such as that shown in FIGS. 4A, 4B, 6A and/or 6B. The data generated by power unit charging module 510 may also be uploaded to one or more remote devices over network 104 via communications module 506. In some embodiments, one or more of the rechargeable battery-powered devices of system 100 can be configured to receive two removable battery packs as power units 512A-512N. For example, rechargeable battery-powered devices 102A, 102B, 102C, and/or 102D can be configured to operate using power provided by only one of the two battery packs. In this regard, when one of the battery packs is depleted below a predetermined threshold, at least one user of system 100 (who may be using a component, such as pharmacy terminal 108, of system 100 located remotely from the associated rechargeable battery-powered device) can be notified to replace the battery, while the second battery pack allows the nurse or other user to continue using the rechargeable battery-powered device. For example, a pharmacy technician could swap depleted batteries with batteries charged by charging unit 110C when the technician restocks the rechargeable battery-powered device with medications and/or when needed. FIG. 7, discussed below, shows an example workflow for swapping batteries.

As another example, when apparatus 500 is implemented as a charging unit, power unit charging module 510 can be a more substantial component of apparatus 500 and still be configured to monitor the health of the power units 512A-512N (e.g., there may be three dozen or more battery packs included in apparatus 500) while they are charged. Similar to the discussion in connection with the rechargeable battery-powered device examples, the data collected during the monitoring process may be stored (by, e.g., memory 504) and/or processed (by, e.g., processor 502) into statistical data, such as that shown in FIGS. 6A and/or 6B. The data generated by power unit charging module 510 may also be uploaded to one or more remote devices over network 104 via communications module 506, and be used to match one or more of power units 512A-512N with one or more rechargeable battery-powered devices getting low on battery power.

As noted above, the various components of system 100 can be configured to collectively operate to monitor and determine, for example, the age and other variables of each battery and each battery-operated device used in system 100 to selectively match one or more batteries with each rechargeable battery-powered device. Some examples of other variables include how long a battery has been in service, how the battery has been treated while in service (e.g., exposure to extreme temperatures, depletion levels, etc.), and the power requirements of the rechargeable battery-powered devices, among other things.

FIG. 7 shows an example process, process 700, including operations that may be executed by system 100 to have one or more drained batteries intelligently swapped for one or more fully-charged (or partially-charged) batteries based on an algorithm built on, for example, the variables discussed herein (among others). For example, non-transitory computer readable media can be configured to store firmware, one or more application programs, and/or other software, which include instructions and other computer-readable program code portions that can be executed to control each processor (e.g., processor 502) of the components of system 100 to implement various operations, including the examples shown in FIG. 7. As such, a series of computer-readable program code portions are embodied in one or more computer program products and can be used, with a computing device, server, and/or other programmable apparatus, to produce a machine-implemented process.

As will be appreciated, any such computer program instructions and/or other type of code may be loaded onto a computer, processor or other programmable apparatus's circuitry to produce a machine, such that the computer, processor other programmable circuitry that execute the code on the machine create the means for implementing various functions, including those described herein. In this regard, the process 700 illustrated by FIG. 7 can be implemented on a rechargeable battery-powered device (such as the processor of rechargeable battery-powered device 102A/102B/102C/102D), a central device (such as central device 106), a user terminal (such as, pharmacy terminal 108), and/or a battery charging unit (such as battery charging unit 110A/110B/110C).

Process 700 starts at 702, and proceeds to 704 where a machine remote from a rechargeable battery-powered device (such as pharmacy terminal 108) can be notified via a signal from another component (such as from a rechargeable battery-powered device 102A and/or central device 106) that a battery needs to be replaced in a rechargeable battery-powered device. For example, the rechargeable battery-powered device and/or central device can be configured to determine when a battery is becoming too depleted to properly power the rechargeable battery-powered device (e.g., based on the DOD information generated by the rechargeable battery-powered device and uploaded via network 104), and then transmit the battery replacement notification signal over the network to the pharmacy terminal and/or other machine of system 100.

In some embodiments, system 100 may determine (e.g., at a central device remote from the rechargeable battery-powered devices) that multiple rechargeable battery-powered devices may need new batteries at or about the same time and/or before a user is expected to be able to complete the swap process. In such instances, some embodiments may be configured to determine which rechargeable battery-powered device should be prioritized for receiving a charged battery. For example, a system may be configured to know that there are a limited number of users authorized to replace depleted batteries in the rechargeable battery-powered devices of a hospital. In prioritizing which rechargeable battery-powered device (s) should receive a new battery first, system 100 can be configured to select a rechargeable battery-powered device by, for example, determining the rechargeable battery-powered devices' expected near-term usage, the available battery power of each rechargeable battery-powered device needing a more-fully charged battery, etc. When the available battery power is being used to help determine which rechargeable battery-powered device has priority, the available battery power for a rechargeable battery-powered device can be determined by, for example, determining the amount of power each battery used by the rechargeable battery-powered device is expected to provide. For example, some rechargeable battery-powered devices may include two batteries, where a first amount of power can be determined that is associated with the rechargeable battery-powered device's first battery (e.g., the battery currently powering the mediation cart) and a second amount of power from a second battery (e.g., a backup or depleted battery). The first and second amounts of power can be summed to determine the available battery power for each rechargeable battery-powered device in need of a battery (e.g., because at least one battery is below a predetermine threshold). In this regard, the rechargeable battery-powered device that has the least amount of available power among all its batteries may be prioritized for having its depleted battery swapped over other rechargeable battery-powered devices that also need to have at least one battery swapped. In some embodiments, the available battery power can be based on selecting the lesser of the first amount of power and the second amount of power. As such, the rechargeable battery-powered device that has the single battery with the highest level of depletion may be prioritized. In addition to using this type of information to select the priority of rechargeable battery-powered devices to receive a more fully charged battery, some embodiments of the invention may also be configured to use this type of analysis to determine the battery to be installed into the selected rechargeable battery-powered device at 706 (discussed below).

In some embodiments, the system may be configured to determine automatically at 704, and in the absence of a notifying signal, when a battery is likely to need to be replaced in a rechargeable battery-powered device. For example, the pharmacy terminal may have access to each rechargeable battery-powered device's historic power usage data (such as that shown in FIGS. 4A and 4B) and each battery's health information and anticipate when the battery is likely to need to be replaced.

At 706, the system can be configured to analyze which of the batteries within the networked charging units are best suited for the rechargeable battery-powered device that is running low on battery power. Further to the discussion above, the determination at 706 can be based on, for example, the calculated remaining lifespan of a battery based on the depth of each discharge cycle, the type of battery, past monitoring of how long each battery has been in service, and/or any other data that may be received or generated by system 100 regarding each battery included in the inventory of system 100. The analysis at 706 can also include processing data associated with the rechargeable battery-powered device. For example, the specific power requirements for that rechargeable battery-powered device can be considered in selecting the battery at 706.

A graphical user interface may then be generated at 706, which can direct the user as to which battery to retrieve from which battery charging unit. For example, FIG. 8 shows display 800, which may be a main menu display that is generated to show the general status and location of each battery deployed throughout system 100. In some embodiments, this information may be conveyed to a user by configuring display 800 to include battery ID column 802, battery location column 804 and battery status column 806. For example, battery ID column 802 can include battery identifying information derived from a barcode and/or RFID tag associated with the battery. Battery location column 804 can include rechargeable battery-powered device information, charging unit identifying information and/or other device identifying information that the system 100 most recently associated with the battery. Battery status column 806 can show each battery's level of discharge/charge (depending on, e.g., whether the battery is being depleted by a rechargeable battery-powered device or charged by a charging unit, respectively), and/or otherwise convey the remaining amount of power and/or other aspect of the battery's status to the user. In some embodiments, the rows of display 800 may also or instead be color coded to convey the same information and/or additional information. For example, a red color indicates that something needs to be performed by a user (e.g., replacement of the battery, etc.), light green can show the batteries that are in use by a rechargeable battery-powered device, and dark green can indicates batteries that are ready to be deployed when needed. In some embodiments, by clicking on or otherwise selecting a battery identified in display 800, the user can be presented a pop-up and/or other display element that presents information for the selected battery. Display 800 may also include one or more selectable tabs, such as main menu option 808, battery data option 810, cart data option 812, charger data option 814, and add/delete battery option 816, which can enable the user to view other information compiled by system 100.

FIG. 9 shows an example notification window 902 that may be presented at 706. For example, at 704 of process 700 of FIG. 7, the battery having the identifier “Batt004” can be determined to be or likely to be at or near 100% DOD. In response, the analysis at 706 can be conducted and at 706 the user can be directed via notification window 902 of FIG. 9 to replace the battery having the identifier “Batt004” with the battery having the associated identifier “Batt008.” In other words, some embodiments can analyze, among other things, the charging cycle of “Batt008” and the duty cycle requirements of the rechargeable battery-powered device having the identifier “Cart004” (in which Batt004 is associated), and system 100 can determine at 706 that Batt008 is the best match for Cart004 among the currently available batteries of system 100 (e.g., chosen from batteries that are fully-charged or will be fully-charged in the near enough future such that functionality of Cart004 would not be interrupted or interrupted minimally).

Returning to FIG. 7, at 708, the user can remove the selected battery (Batt008) from the charging unit (e.g., “Charger 3000” as shown in FIG. 8), and physically carry the selected battery (Batt008) to the selected rechargeable battery-powered device (Cart004). In some embodiments, system 100 can be configured to provide the user location information as to where the charging unit (or other type of origination device) and/or rechargeable battery-powered device (or other type of destination device) is located within a given area (e.g., within a hospital). For example, system 100 may present a display that indicates Batt008 is in a charging unit in the pharmacy and that Cart004 is on the third floor of the maternity ward of the hospital. More or less detailed location information (including none) may be provided by some embodiments.

At 710, the user can initiate execution of an application (e.g., such as a software or other type of application) at the rechargeable battery-powered device (Cart004) to enable the depleted battery (Batt004) to be removed from the rechargeable battery-powered device and the fully-charged battery (Batt008) to be installed. The application can, for example, provide the user instructions for how to remove the battery, authenticate the user, unlock any necessary security protocols that aid in preventing unauthorized removal of the battery, place the rechargeable battery-powered device into a state where removing the battery will not cause any damage or problems to the functionality of the rechargeable battery-powered device, inform the user of the location of the battery to be removed (if, e.g., there is more than one battery being used by the rechargeable battery-powered device), and/or require the rechargeable battery-powered device is plugged into an alternate power source, among other things.

At 712, the user physically removes the depleted battery (Batt004) from the rechargeable battery-powered device. An acknowledgement or error message may be presented to the user depending on whether the user removes the correct battery from the rechargeable battery-powered device and/or removes the battery correctly.

At 714, the charged battery's identifying data can be inputted into the system and the charged battery can be inserted into the rechargeable battery-powered device. For example, the charged battery's identification information (Batt008) can be read automatically by the rechargeable battery-powered device using a barcode scanner incorporated in the battery compartment of the rechargeable battery-powered device, manually entered using a keyboard included in the rechargeable battery-powered device, retrieved using a RFID reader within range of the battery's RFID tag, and/or otherwise inputted into the rechargeable battery-powered device. In some embodiments, another component of system 100 (such as a handheld device, which is not shown in FIG. 1 but can be used by the user) can be used to input the battery's identifying data into system 100. For example, a handheld, networked barcode scanner can read a battery's barcode and upload the battery identifying information to central device 106 and/or any other component of system 100 for logging, monitoring and/or other purposes.

At 716, system 100 can be configured to associate the charged battery (Batt008) with the cart (Cart004) in a system database, such as a database maintained by central device 106 and/or any other suitable storage device. For example, the next time a user accesses a display similar to that shown in FIG. 8, the location of Batt008 can be shown as Cart004, the color of the row for Batt008 can be different, and, rather than show the amount of charge remaining, system 100 may present the depth of discharge of Batt008 as reported by Cart004 and/or Batt008 itself via network 104. In this regard, none, some or all of the batteries discussed herein may be networked devices, which may have circuitry such as that discussed in connection with FIG. 5 and can connect directly to network 104 of FIG. 1 in addition to or instead of rechargeable battery-powered devices and/or charging units providing at least some of battery information to network 104.

At 718, the user closes the battery application on the rechargeable battery-powered device, which may result in, for example, the rechargeable battery-powered device locking the battery compartment of the rechargeable battery-powered device, logging data regarding the interaction (e.g., how long the user was in the battery compartment), starting a timer for how long the battery is unassociated with a device while in transit to a charger, etc.

At 720, the user may return to performing other activities, including returning to the pharmacy, stocking other supplies into the rechargeable battery-powered device, etc.

At 722, the user may bring the depleted battery to a charging unit, cause the uploading of the battery identifier to system 100 (e.g., by scanning a barcode, installing the battery into the charging unit, etc.), and/or cause the uploading of the charging unit identifier to system 100. System 100 may then assign the depleted battery (Batt004) to the new charging unit at 724, and store the data in a database for later retrieval and/or presentation of displays, such as that shown in FIG. 8. At 726, process 700 ends.

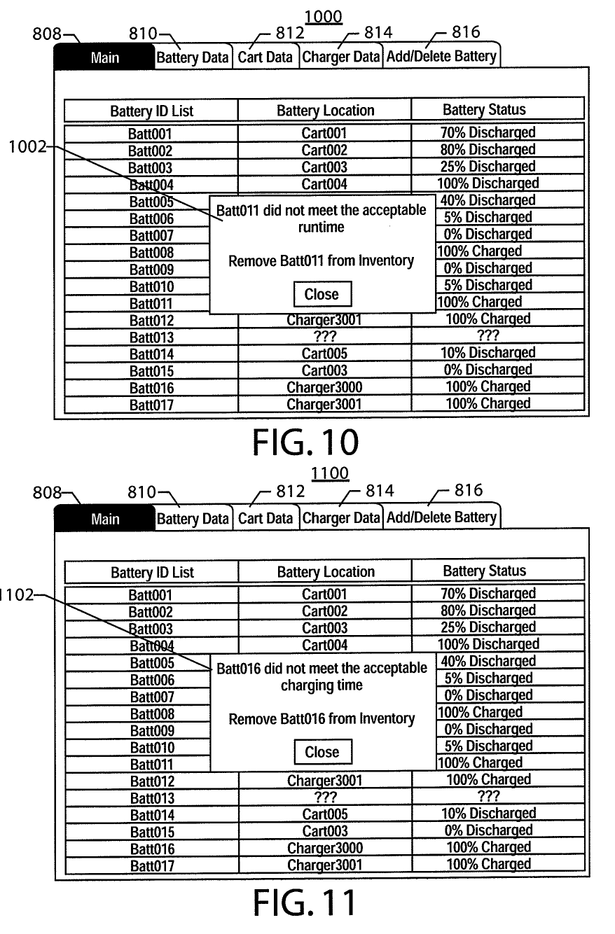

FIG. 10 shows display 1000, which includes message notification 1002 that may be presented when, for example, a battery fails to provide power to a rechargeable battery-powered device (or other device) for at least a predetermined minimum runtime threshold. For example, each battery in system 100 may be required to provide at least 5 hours of power to a rechargeable battery-powered device that has been rated as having a relatively lower power requirement. When, for example, a battery, such as “Batt011,” fails to meet the minimum acceptable runtime, message notification 1002 can be presented. In this regard, when a battery is installed into a rechargeable battery-powered device at, e.g., 714 of FIG. 7, a timer may be started in order to track the amount of time before the battery's depth of discharge is such that the battery needs to be replaced with a charged battery.

Similarly, as shown in display 1100 of FIG. 11, the amount of time a battery takes to charge may be used to determine the health of the battery. When, for example, a battery, such as “Batt016,” is determined to be unhealthy as a result of failing to meet the acceptable charging time, message notification 1102 can be presented to a user. In this regard, when a battery is installed into a charging unit at, e.g., 722 of FIG. 7, a timer may be started in order to track the amount of time before the battery's level of charge is at an acceptable level. As discussed in connection with FIGS. 6A and 6B, a healthy battery generally takes longer than an unhealthy battery for the applied voltage potential to rise and current to levels to drop while charging.

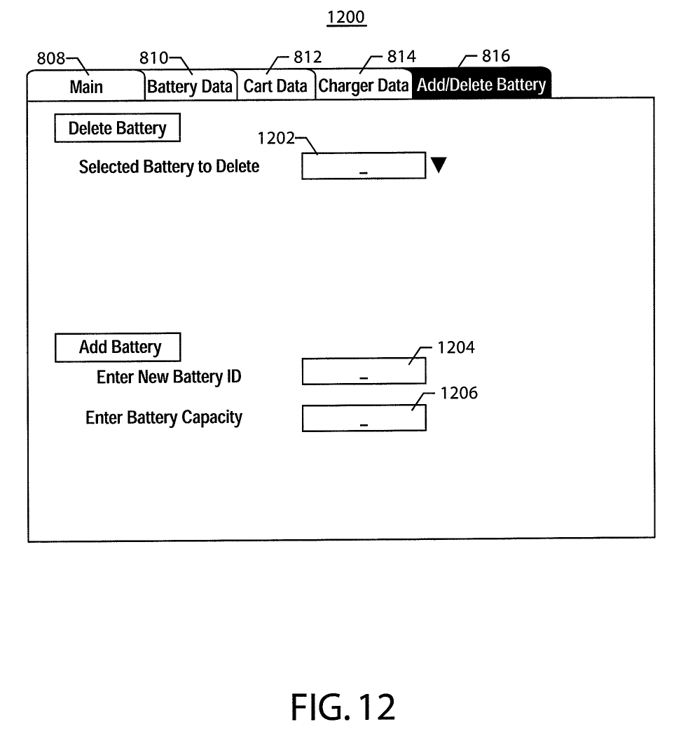

In response to receiving message notification 1002 and/or message notification 1102, the user may select add/delete battery option 816. In response, a graphical user interface, such as display 1200 of FIG. 12, may be presented. In the example shown, a pull down menu and/or other form of data entry may be provided using input field 1202 to identify a battery to be removed from system 100's inventory. Upon removing the battery from the system 100's inventory, the battery may be sent for reconditioning, recycling, donation, storage and/or otherwise culled from system 100.

In some embodiments, display 1200 may also be configured to enable a user to add a new battery to system 100's inventory. For example, display 1200 may include data input field 1204 and data input field 1206, which may enable the user to manually enter a new battery identifier and other details about the new battery, such as the battery's capacity. In some embodiments, in addition to or instead of the user manually entering the battery information into data input fields 1204 and/or 1206, the battery information may be obtained automatically by system 100. In such embodiments, data input fields 1204 and/or 1206 may be used to confirm information automatically obtained. For example, data input field 1204 may show information obtained from automatically scanning, for example, a barcode included on the battery and/or data input field 1206 may show data retrieved from a remote location (such as a manufacturer's networked database) to confirm that the proper information regarding the battery has been pulled down into system 100 (by comparing what is downloaded and presented to the information printed on the battery).

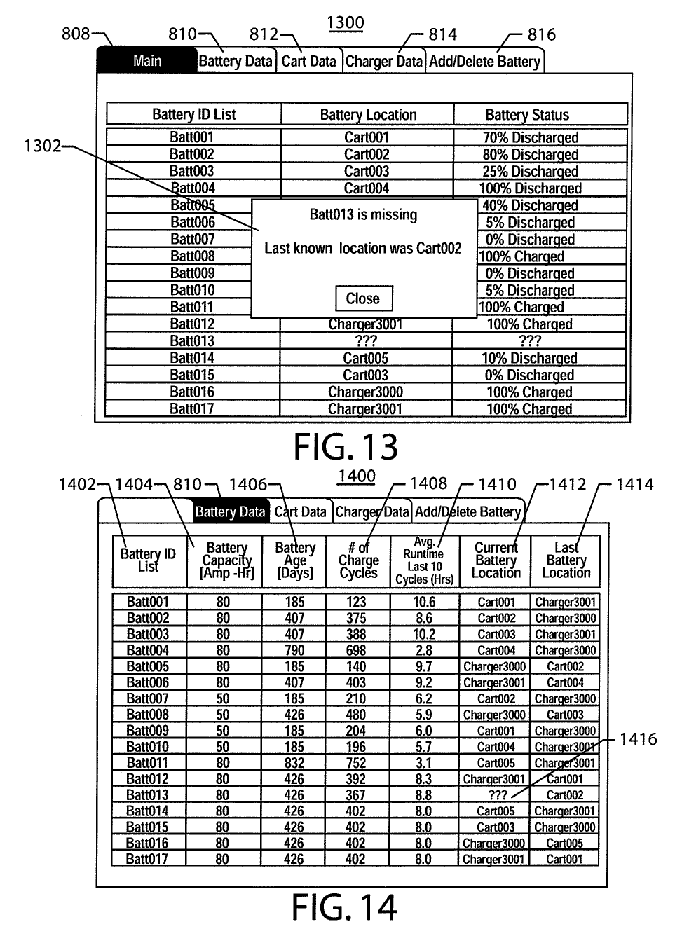

System 100 may also be configured to start a timer and monitor the amount of time it takes for a battery to be physically removed from an origination component (e.g., rechargeable battery-powered device or charging unit) and installed into a destination component (e.g., charging unit or rechargeable battery-powered device). For example, the amount of time between 708 and 714 of process 700 can be monitored and/or the amount of time between 712 and 722 can be monitored by system 100. In response to a predetermined threshold of time being exceeded, one or more components of system 100 can be configured to inform the user that a battery is missing or otherwise unaccounted for. For example, FIG. 13 shows display 1300 that includes notification message 1302 that presents the battery identifier of a battery that is unaccounted for as well as the last known location of the battery. In this regard, one or more users can begin the process of searching for the current location of the battery, which may be helpful in avoiding the loss of batteries as well as assuring depleted batteries are promptly placed in charging units upon their removal from rechargeable battery-powered devices. In this regard, monitoring the location of a battery may also help minimize the number of situations where there are not enough charged batteries in the inventory, and enable system 100 to function with the smallest possible inventory (which can save money as such batteries can be expensive). In some embodiments, like other threshold values discussed herein, the amount of time before triggering such a notification message can be preconfigured into system 100, be configured by a user, be associated with the type of battery (e.g., more expensive batteries can be given a shorter unaccounted for time window), be user specific (e.g., the user who removes the battery may be given a threshold based upon the user's level of responsibilities and/or to-do list), and/or be dynamically configured (e.g., shorten or lengthen the time allowed based upon the number of missing battery notifications that have been historically generated over a given period of time, such as the past month).

FIG. 14 shows display 1400, which may be presented in response to the user selecting battery data option 810. Display 1400 is shown as including specific information for each of the batteries in system 100's inventory. Although display 1400 may be configured in any suitable manner, the example shown includes: column 1402 identifying each battery's identifying information, column 1404 identifying each battery's capacity rating (e.g., in Ah), column 1406 identifying each battery's age (e.g., in days), column 1408 identifying each battery's completed charge cycles (e.g., in number of cycles), column 1410 identifying each battery's average time to reach 100% DOD over a predetermined number of past cycles (e.g., average run time in hours over the past 10 cycles), column 1412 identifying each battery's current location, and/or column 1414 identifying each battery's previous location. The data from, for example, columns 1404, 1406, 1408 and 1410 can be used by some embodiments to determine the health of the battery, which can then be used to match the battery to a rechargeable battery-powered device and/or other device. In some embodiments, the information of columns 1412 and 1414 can also be used to determine the battery's health, as the cart in which the battery was used may impact, for example, the associated average runtime value of column 1410. In some embodiments, an indication such as indicator 1416 may be included when the battery is in transit between components of system 100 and/or when the location of the battery is currently unaccounted for.

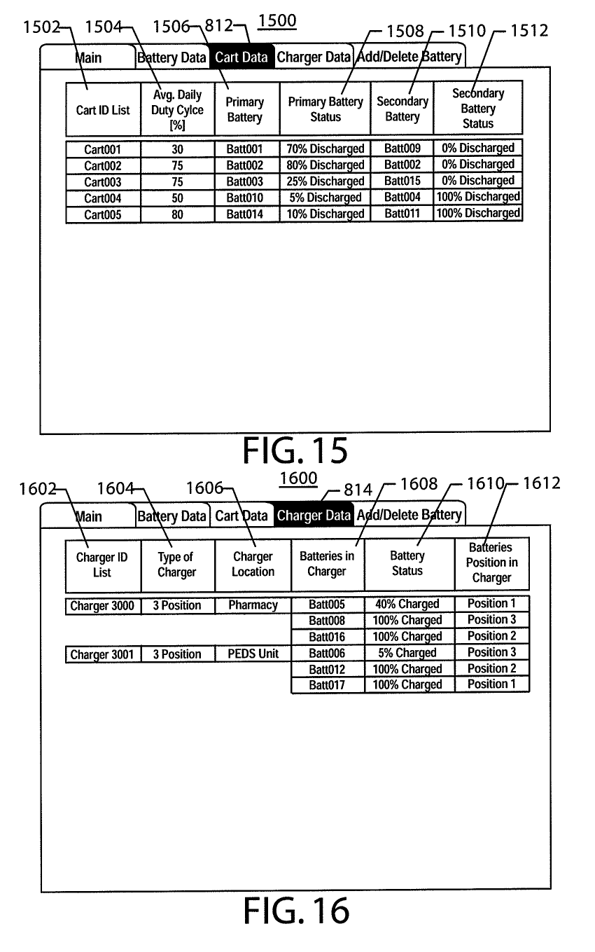

FIG. 15 shows display 1500, which may be presented in response to the user selecting cart data option 812. Display 1500 is shown as including specific information for each of the rechargeable battery-powered devices, which may be the same as or similar to rechargeable battery-powered devices 102A, 102B, 102C and 102D discussed in connection with FIG. 1, in system 100's inventory. Although only four rechargeable battery-powered devices are shown in FIG. 1, more or less may be shown as represented by FIG. 15's inclusion of five rechargeable battery-powered devices. In the example shown by display 1500: column 1502 identifies each rechargeable battery-powered device's identifying information, column 1504 identifies each rechargeable battery-powered device's average duty cycle (e.g., which defines the time that a cart is being used by an operator over a specific total timeframe), column 1506 identifies each rechargeable battery-powered device's first battery (e.g., the battery identifier associated with the battery that is currently supplying power to the respective rechargeable battery-powered device), column 1508 identifies each rechargeable battery-powered device's first battery status (e.g., the DOD of the first battery), column 1510 identifies each rechargeable battery-powered device's second battery (e.g., the battery identifier of the second battery in the cart which may be a backup battery, dysfunctional battery, or depleted battery needing exchanging), and column 1512 identifies each rechargeable battery-powered device's second battery status (e.g., the DOD of the second battery). In some embodiments, display 1500, like other displays discussed herein, can use colors, fonts, and/or any other display elements to highlight and/or otherwise convey information to a user, such as whether a battery is fully discharged and/or fully charged. For example, batteries that are 100% discharged can be highlighted in red, while batteries that are 0% discharged can be highlighted in green.

FIG. 16 shows display 1600, which may be presented in response to the user selecting charger data option 814. Display 1600 is shown as including specific information for each of the charger units in system 100's inventory. Although FIG. 16 only shows two charging units each being able to charge three batteries (e.g., battery packs), more or less charging units having other capacities may or may not be included in system 100. In the example shown by display 1600: column 1602 identifies each charging unit's identifying information (collectively, column 1602 can show a list of all the charging units in system 100), column 1604 identifies each charging unit's type (e.g., how many charging positions are in the unit, model number, make, etc.), column 1606 identifies each charging unit's location (e.g., where the charging unit is located within a facility), column 1608 identifies the batteries in each position of the charging unit (e.g., by providing a list of the battery identifying information of the batteries that are currently in the charging unit), column 1610 identifies the status of each battery in each position of the charging unit (e.g., by providing the state of charge for each of the batteries), and column 1612 identifies the position of each battery in each of the charging units (e.g., by showing the location of each battery in the charging unit).

As such, system 100 can be configured to present displays that provide an intuitive user experience. When a user receives an alarm or alert generated by system 100, the user can understand that something must be done quickly to ensure that the device(s) can stay fully operational. For example, the user may understand that even if a charged battery is not available, the user may understand that a rechargeable battery-powered device needs to be plugged in to an AC outlet. In this regard, although the displays shown herein were discussed in connection with a terminal, such as pharmacy terminal 108, one or more of the displays and/or the information conveyed therein may be presented by any other component included in system 100, such as by a rechargeable battery-powered device, by a battery charging unit, by a cellular phone of the user (not shown in FIG. 1), by a tablet (not shown in FIG. 1), and/or by any other suitable device. System 100 may also be configured to consider variables such as the relative lack of mobility of a rechargeable battery-powered device that is or needs to be plugged-in. Likewise, when a battery needs to be swapped, a nurse or other user may have to divert time from their traditional duties (e.g., patient care) to locate a battery for replacement or de-mobilize the rechargeable battery-powered device, and system 100 can be configured to consider this when determining which component of system 100 to use to provide various notifications, such as the notification shown in FIG. 9. Some embodiments may also include an urgent button that may cause the system to prioritize the particular rechargeable battery-powered device for replenishment of a charged battery.

All or some of the information presented by the example displays discussed herein can be based on data that is received, generated and/or maintained by one or more components of system 100. For example, the data may be based on monitoring activities conducted by the components of system 100 and stored in a database maintained as part of system 100. In some embodiments, one or more external systems (such as a remote cloud computing and/or data storage system) may also be leveraged to provide at least some of the functionality discussed herein.

As described above and as will be appreciated based on this disclosure, embodiments of the present invention may be configured as methods, rechargeable battery-powered devices central network devices, battery charging units, and the like. Accordingly, embodiments may comprise various means including entirely of hardware or any combination of software and hardware. Furthermore, embodiments may take the form of a computer program product on at least one nontransitory computer-readable storage medium having computer-readable program instructions (e.g., computer software) embodied in the storage medium. Any suitable computer-readable storage medium may be utilized including non-transitory hard disks, CD-ROMs, flash memory, optical storage devices, or magnetic storage devices.

Embodiments of the present invention have been described above with reference to block diagrams and flowchart illustrations of methods, apparatuses, systems and computer program products. It will be understood that each block of the circuit diagrams and process flowcharts, and combinations of blocks in the circuit diagrams and process flowcharts, respectively, can be implemented by various means including computer program instructions. These computer program instructions may be loaded onto a general purpose computer, special purpose computer, or other programmable data processing apparatus, such as processor 502 discussed above with reference to FIG. 5, to produce a machine, such that the computer program product includes the instructions which execute on the computer or other programmable data processing apparatus create a means for implementing the functions specified in the flowchart block or blocks.

These computer program instructions may also be stored in a computer-readable storage device (e.g., memory 504) that can direct a computer or other programmable data processing apparatus (e.g., processor 502 of FIG. 5) to function in a particular manner, such that the instructions stored in the computer-readable storage device produce an article of manufacture including computer-readable instructions for implementing the function discussed herein. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions discussed herein.

Accordingly, blocks of the block diagrams and flowchart illustrations support combinations of means for performing the specified functions, combinations of steps for performing the specified functions and program instruction means for performing the specified functions. It will also be understood that each block of the circuit diagrams and process flowcharts, and combinations of blocks in the circuit diagrams and process flowcharts, can be implemented by special purpose hardware-based computer systems that perform the specified functions or steps, or combinations of special purpose hardware and computer instructions.

Many modifications and other embodiments of the inventions set forth herein will come to mind to one skilled in the art to which these embodiments of the invention pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. For example, while the many of the examples used herein often refer to hospital-related technologies (such as, decentralized medication storage and dispensing devices and med shifts, e.g., the time a nurse spends dispensing medications), embodiments discussed herein may be applied in other types of technologies and systems, including those used in laptop computers, cellular phones, forklifts, electric automobiles, electric motorbikes, and/or any other battery-powered device. Although specific terms are employed herein, they are used in a generic and descriptive sense only and not for purposes of limitation.

That which is claimed:

1. A method of monitoring available power supplies for rechargeable battery-powered devices, comprising:
receiving battery data indicating an amount of energy stored by a battery;
determining an amount of power the battery is expected to provide from the amount of energy;
receiving an expected power usage value associated with a rechargeable battery-powered device; and
determining the battery is to be installed into the rechargeable battery-powered device based at least partially on the expected power usage value associated with the rechargeable battery-powered device and the amount of power the battery is expected to provide.

2. The method of claim 1, wherein determining the amount of power the battery is expected to provide comprises analyzing the battery's usage history.

3. The method of claim 2, wherein analyzing the usage history comprises determining the battery's length of service.

4. The method of claim 2, wherein analyzing the usage history comprises determining a number of charge cycles the battery has undergone.

5. The method of claim 2, wherein analyzing the usage history comprises determining the battery's average run time over a predetermined number of discharge cycles.

6. The method of claim 1, wherein determining the battery is to be installed into the rechargeable battery-powered device further comprises determining an available battery power of the rechargeable battery-powered device.

7. The method of claim 6, wherein determining the available battery power includes:
determining a first amount of power a first battery is expected to provide the rechargeable battery-powered device;
determining a second amount of power a second battery is expected to provide the rechargeable battery-powered device; and
summing the first amount of power and the second amount of power to equal the available battery power.

8. The method of claim 6, wherein determining the available battery power includes:
determining a first amount of power that a first battery is expected to provide the rechargeable battery-powered device;
determining a second amount of power that a second battery is expected to provide the rechargeable battery-powered device; and
selecting the lesser of the first amount of power and the second amount of power as the available battery power.

9. The method of claim 1 further comprising:
determining when the rechargeable battery-powered device is scheduled to be attended to by a user; and
in response to determining when the rechargeable battery-powered device is scheduled to be attended to by the user, generating a display instructing the user to install the battery in the rechargeable battery-powered device with the restocking of the rechargeable battery-powered device.

10. The method of claim 9 further comprising, in response to determining the battery is to be installed into the rechargeable battery-powered device, generating a display indicating a location of the battery.

11. The method of claim 1 further comprising, in response to determining the battery is to be installed into the rechargeable battery-powered device, generating a display indicating a location of the rechargeable battery-powered device.

12. A system comprising:
communications circuitry configured to:
receive battery data indicating an amount of energy stored by a battery; and
receive an expected power usage value associated with a rechargeable battery-powered device; and
a processor configured to:
determine an amount of power the battery is expected to provide from the amount of energy; and
determine the battery is to be installed into the rechargeable battery-powered device based at least partially on the expected power usage value associated with the rechargeable battery-powered device and the amount of power the battery is expected to provide.

13. The system of claim 12, wherein the processor is further configured to determine the amount of power by analyzing the battery's usage history.

14. The system of claim 13, wherein the processor being configured to analyze the usage history comprises the processor configured to determine the battery's length of service.

15. The system of claim 13, wherein the processor being configured to analyze the usage history comprises the processor configured to determine a number of charge cycles the battery has undergone.

16. The system of claim 13, wherein the processor being configured to analyze the usage history comprises the processor configured to determine the battery's average run time over a predetermined number of discharge cycles.

17. The system of claim 12, wherein the processor being configured to determine the battery is to be installed into the rechargeable battery-powered device is further based partially on determining an available battery power of the rechargeable battery-powered device.

18. The system of claim 12, wherein the processor being configured to determine the battery is to be installed into the rechargeable battery-powered device is further based partially on when the rechargeable battery-powered device is scheduled to be attended to by a user.

19. The system of claim 12 further comprising the communication component configured to generate a signal that causes a remote display screen to display information indicating where the battery is to be found by a user.

20. The system of claim 12 further comprising the communication component configured to generate a signal that causes a remote display screen to display information indicating where the rechargeable battery-powered device is to be found by a user.

21. A computer program product, the computer program product comprising at least one non-transitory computer-readable storage medium having computer-readable program code portions stored therein, the computer-readable program code portions comprising:
an executable portion configured to receive battery data indicating an amount of energy stored by a battery;
an executable portion configured to determine an amount of power the battery is expected to provide from the amount of energy;
an executable portion configured to receive an expected power usage value associated with a rechargeable battery-powered device; and
an executable portion configured to determine the battery is to be installed into the rechargeable battery-powered device based at least partially on the expected power usage value associated with the rechargeable battery-powered device and the amount of power the battery is expected to provide.
